(19) United States
(12) Patent Application Publication
(10) Pub. No.: US 2026/0040481 A1
(43) Pub. Date: Feb. 5, 2026

(54) COOLING FAN WITH DATA DISPLAY FUNCTION

(71) Applicant: Guangzhou Juchuang Electronic Technology Co., Ltd., Guangdong (CN)

(72) Inventors: Hao XUN, Guangdong (CN); Chao WU, Guangdong (CN); Jiawei LV, Guangdong (CN)

(73) Assignee: Guangzhou Juchuang Electronic Technology Co., Ltd., Guangdong (CN)

(21) Appl. No.: 19/026,193

(22) Filed: Jan. 16, 2025

(30) Foreign Application Priority Data
Jul. 30, 2024 (CN) 202421818994.3

(51) Int. Cl. H05K 7/20; F04D 25/06

(52) U.S. Cl. CPC H05K 7/20172; F04D 25/0693

(57) ABSTRACT

A cooling fan with a data display function includes a frame body, a driving unit and a fan blade, the driving unit being mounted on the frame body, the fan blade being connected to the driving unit, the driving unit driving the fan blade to rotate. The driving unit includes a PCB board, a stator part, a rotor part and a nixie tube, the PCB board, the stator part and the nixie tube are disposed sequentially from the inside to the outside, the stator part is electrically connected to the PCB board, and the rotor part is matched with the stator part to rotate. A pin of the nixie tube passes through a spacing of the stator part to be electrically connected to the PCB board.

### CROSS-REFERENCE TO RELATED APPLICATION

This application claims the priority benefit of China application serial no. 202421818994.3, filed on Jul. 30, 2024. The entirety of the above-mentioned patent application is hereby incorporated by reference herein and made a part of this specification.

### BACKGROUND

### Technical Field

The present disclosure relates to cooling fans, and in particular to a cooling fan with a data display function.

### Description of Related Art

As a conventional device for reducing equipment temperature and ambient temperature in industries and daily life, cooling fan creates a local air convection through simple rotary movement of blades, thereby dispersing hot air and achieving the purpose of cooling. Especially, along with recent rapid developments of science and technology, cooling fan as a peripheral for electronic products plays an indispensable role in dispersing heat generated during the operation of the electronic products.

At present, commercial cooling fans have become mature and come in many types, such as axial flow fans, centrifugal fans, mixed flow fans, cross-flow fans, etc. However, for these existing cooling fans, one cannot intuitively understand their direction of rotation (clockwise/counterclockwise), speed of rotation and other data, which leads to deficiencies in the use of these fans. It is therefore necessary to upgrade and improve the cooling fans in the prior art.

### SUMMARY

One object of the present disclosure is to provide a cooling fan with a data display function that can be intuitively viewed by users and has improved visual effects and a simple structure.

In order to solve the aforesaid technical problems, this disclosure can be implemented by the following technical solutions.

A cooling fan with a data display function comprises a frame body, a driving unit and a fan blade, the driving unit being mounted on the frame body, the fan blade being connected to the driving unit, the driving unit driving the fan blade to rotate. The driving unit comprises a PCB board, a stator part, a rotor part and a nixie tube, the PCB board, and the stator part and the nixie tube are disposed sequentially from inside to outside. The stator part is electrically connected to the PCB board, the rotor part is matched with the stator part to rotate, and a pin of the nixie tube passes through a spacing of the stator part to be electrically connected to the PCB board.

In one embodiment, the nixie tube has a control circuit board, and a pin of the control circuit board passes through the spacing of the stator part to be electrically connected to the PCB board.

In one embodiment, the driving unit further comprises a light-transmitting member, which is covered on the nixie tube and connected to the rotor part to rotates therewith, and the fan blade is connected to the light-transmitting member.

In one embodiment, the fan blade comprises a sleeve and a plurality of blades, the sleeve is provided on the light-transmitting member, and the plurality of blades are evenly distributed on an outer side wall of the sleeve.

In one embodiment, an interference fit is formed between the sleeve and the light-transmitting member.

In one embodiment, the frame body comprises an outer frame and a fixing plate, the fixing plate is located in the middle of the outer frame and connected to the outer frame through a plurality of connecting ribs, and the driving unit is mounted on the fixing plate.

In one embodiment, one of the connecting ribs is provided with a clamping groove.

In one embodiment, shock absorbing pads are provided at four corners on both sides of the outer frame.

In one embodiment, the cooling fan with a data display function further comprises a controller electrically connected to the driving unit.

### Advantageous Effects

In the present cooling fan with a data display function, the driving unit is mounted on the frame body, the PCB board, the stator part and the nixie tube in the driving unit are disposed sequentially from the inside to the outside, and at the same time, a pin of the nixie tube passes through the spacing of the stator part to be electrically connected to the PCB board. With such an arrangement, the nixie tube can be supported by the pin, making the structure simpler. Moreover, the connection with the PCB board through the pin can also realize signal transmission and power supply, and various data can be displayed via the nixie tube, so that it is convenient for users to view the data intuitively, while the data light displayed by the nixie tube can further improve the visual effect of the cooling fan.

### BRIEF DESCRIPTION OF THE DRAWINGS

FIG. 1 is an exploded view of the cooling fan with a data display function of the present disclosure;

FIG. 2 is a sectional view of the cooling fan with a data display function of the present disclosure; and

FIG. 3 is a diagram showing the frame body structure of the cooling fan with a data display function of the present disclosure.

### DESCRIPTION OF THE EMBODIMENTS

In order to make the above-mentioned objects, features and advantages of the present disclosure more apparent, specific embodiments of the present disclosure will be described below in conjunction with the accompanying drawings. Many specifics are set forth in the following description in order to facilitate a full understanding of the present disclosure. However, the present disclosure may be implemented in many other ways different from those described herein, and those skilled in the art could make similar improvements without departing from the spirit of the present disclosure. Therefore, the present disclosure is not limited by the specific embodiments disclosed below.

It should be noted that when an element is referred to as being “fixed to” another element, it may be directly on the other element or intervening elements may be present. When an element is considered to be “connected” to another element, it may be directly connected to the other element or intervening elements may be present at the same time. In contrast, when an element is referred to as being “directly on” another element, there are no intervening elements present. The terms “vertical”, “horizontal”, “left”, “right” and similar expressions used herein are for illustrative purposes only.

Unless otherwise defined, all technical and scientific terms used herein have the same meaning as commonly understood by one of ordinary skill in the art to which the exemplary embodiments belong. The terms used herein are only for the purpose of describing specific embodiments and are not intended to limit the present unity model. As used herein the term “and/or” includes any and all combinations of one or more of the associated listed items.

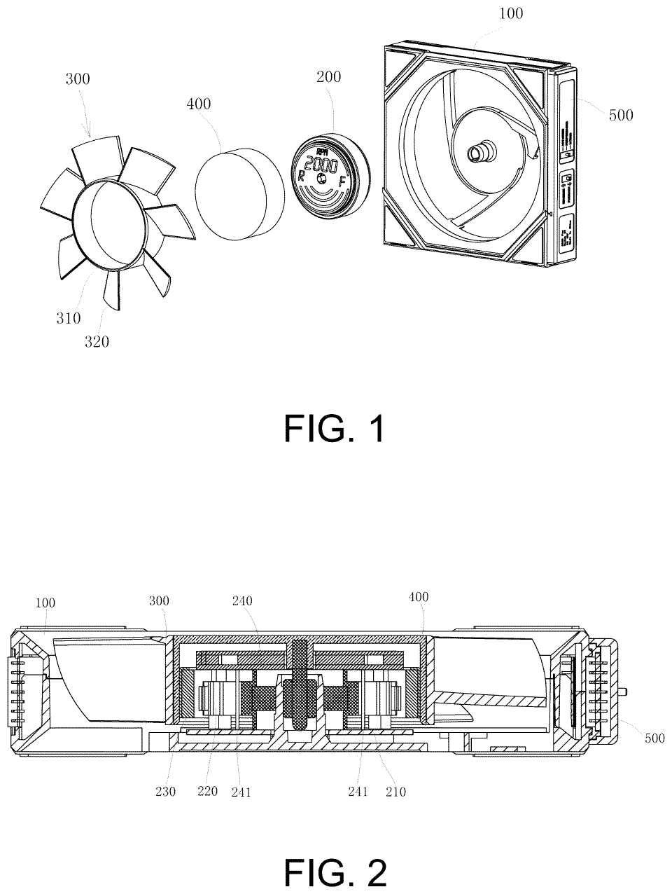

Referring to FIG. 1 and FIG. 2, a cooling fan with a data display function comprises a frame body 100, a driving unit 200 and a fan blade 300. The driving unit 200 is mounted on the frame body 100, and the fan blade 300 is connected to the driving unit 200. The driving unit 200 drives the fan blade 300 to rotate. The driving unit 200 comprises a PCB board 210, a stator part 220, a rotor part 230 and a nixie tube 240. The PCB board 210, the stator part 220 and the nixie tube 240 are disposed sequentially from the inside to the outside, and the stator part 220 is electrically connected to the PCB board 210. The rotor part 230 is matched with the stator part 220 to rotate. A pin 241 of the nixie tube 240 passes through the spacing of the stator part 220 and is electrically connected to the PCB board 210.

Specifically, in this embodiment, the driving unit 200 is mounted on the frame body 100, and the fan blade 300 is connected to the driving unit 200. The driving unit 200 can drive the fan blade 300 to rotate, thereby realizing the cooling function. Moreover, in mounting the driving unit 200, the PCB board 210, the stator part 220 and the nixie tube 240 in the driving unit 200 are arranged sequentially from the inside to the outside, the stator part 220 is electrically connected to the PCB board 210, and the rotor part 230 is matched with the stator part 220 to carry out rotation and to drive the fan blade 300 to rotate. The PCB board 210, the stator part 220 and the rotor part 230 in the driving unit 200 pertain to the prior art, and thus no more details are provided thereon. At the same time, the pin 241 of the nixie tube 240 can directly pass through the spacing of the stator part 220 and be electrically connected to the PCB board 210, such that the nixie tube 240 can be supported by the pin 241, making the overall structure of the driving unit 200 simpler and the layout reasonable. In addition, the electrical connection between the pin 241 of the nixie tube 240 and the PCB board 210 can also realize signal transmission and power supply to the nixie tube 240. Various data transmitted, such as direction of rotation, speed of rotation, range of speed and the like, can be displayed via the nixie tube 240, so as to facilitate users to intuitively view the data and improve the overall practicality of the cooling fan. Besides, the data light displayed by the nixie tube 240 can further improve the overall visual effect of the cooling fan.

Of course, in another embodiment, a control circuit board (not shown in the drawings) may be separately provided for the nixie tube 240 to achieve a dual circuit board structure. During assembly, it is sufficient to similarly pass a pin of the control circuit board through the spacing of the stator part 220 to electrically connect the PCB board 210. By providing a separate control circuit board for the nixie tube 240, the nixie tube 240 can be controlled more conveniently.

Furthermore, in order to control the cooling fan, the cooling fan with a data display function in this embodiment further comprises a controller 500, which may be hardware or software. If hardware control is adopted, the controller 500 may be disposed on one side of the frame body 100, or in the vicinity of the driving unit 200, and the controller 500 is electrically connected to the driving unit 200. The driving unit 200 may be controlled by the controller 500, so as to realize the clockwise or counterclockwise rotation of the fan blade 300, and the rotation speed of the fan blade 300 and the like may also be controlled. Similarly, the controlling of the driving unit 200 may also be achieved via software. Of course, the controller 500 is not indispensable, and it may be selected according to actual production needs. Whether the controller 500 is provided or not will not affect the data display function of the nixie tube 240.

Referring to FIG. 1 and FIG. 2, in order to protect the nixie tube 240, the driving unit 200 in this embodiment also comprises a light-transmitting member 400. During assembly, the light-transmitting member 400 is covered on the nixie tube 240 and connected to the rotor part 230 so that it rotates along with the rotor part 230, and the fan blade 300 is sleeved with the light-transmitting member 400. Through the light-transmitting member 400, protection of the nixie tube 240 can be achieved, and through the light-transmitting member 400 with a transmittance in the range, data displayed on the nixie tube 240 can be clearly viewed from the outside, thus making the cooling fan more convenient in use. The light-transmitting member 400 can also transmit the light displayed by the nixie tube 240, so that the cooling fan has a light effect when in use, thereby improving the visual aesthetics of the cooling fan.

Referring to FIG. 1, in this embodiment, in order to realize the connection between the fan blade 300 and the driving unit 200, the fan blade 300 comprises a sleeve 310 and a plurality of blades 320. During connection, the sleeve 310 is directly provided on the light-transmitting member 400, so that the sleeve 310 and the light-transmitting member 400 are interference-fitted, while the plurality of blades 320 are evenly distributed on the outer side wall of the sleeve 310. Through the interference connection between the sleeve 310 and the light-transmitting member 400, the fan blade 300 can be conveniently disassembled and assembled as a whole, and the fan blade 300 of different specifications, such as fan blades 300 of different colors, different materials, and different blade types, can be conveniently replaced, so as to meet different user needs.

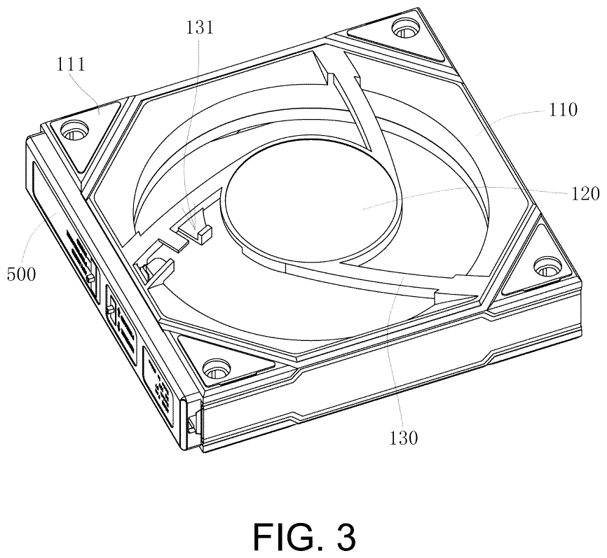

Referring to FIG. 3, in order to mount the driving unit 200, the frame body 100 in this embodiment comprises an outer frame 110 and a fixing plate 120. The fixing plate 120 is located in the middle of the outer frame 110 and connected to the outer frame 110 through a number of connecting ribs 130, and the driving unit 200 is mounted on the fixing plate 120. Meanwhile, one of the connecting ribs 130 is provided with a clamping groove 131, through which a wire connecting the controller 500 and the driving unit 200 can be limited, thus making the wiring convenient and simple.

Finally, in order to avoid excessive noise being generated by the cooling fan when in use, shock absorbing pads 111 are provided in this embodiment at four corners of the outer frame 110 on both sides. Using the shock absorbing pads 111 to dampen the cooling fan, noise generated by the cooling fan when in use can be effectively reduced, and the practicality of the cooling fan can be improved.

The foregoing shows and describes the basic principles and main features of the present disclosure and the advantages thereof. A person skilled in the art could smoothly implement the present disclosure as shown in the accompanying drawings and as described above. However, those skilled in the art could make some changes, modifications, and evolutions on the basis of the technical content disclosed above, without departing from the scope of the technical solutions of this disclosure, which shall all be deemed equivalent embodiments of this disclosure. Meanwhile, any equivalent changes, modifications, evolutions and the like made to the above embodiments based on the substantive technology of this disclosure shall still fall within the scope of the present disclosure.

What is claimed is:

1. A cooling fan with a data display function, comprising: a frame body, a driving unit and a fan blade, the driving unit being mounted on the frame body, the fan blade being connected to the driving unit, the driving unit driving the fan blade to rotate,
wherein the driving unit comprises a PCB board, a stator part, a rotor part and a nixie tube, the PCB board, the stator part and the nixie tube are disposed sequentially from inside to outside, the stator part is electrically connected to the PCB board, and the rotor part is matched with the stator part to rotate, and
wherein a pin of the nixie tube passes through a spacing of the stator part to be electrically connected to the PCB board.

2. The cooling fan with a data display function according to claim 1, wherein the nixie tube has a control circuit board, and wherein a pin of the control circuit board passes through the spacing of the stator part to be electrically connected to the PCB board.

3. The cooling fan with a data display function according to claim 1, wherein the driving unit further comprises a light-transmitting member, which is covered on the nixie tube and connected to the rotor part to rotates therewith, and wherein the fan blade is connected to the light-transmitting member.

4. The cooling fan with a data display function according to claim 3, wherein the fan blade comprises a sleeve and a plurality of blades, the sleeve is provided on the light-transmitting member, and the plurality of blades are evenly distributed on an outer side wall of the sleeve.

5. The cooling fan with a data display function according to claim 4, wherein an interference fit is formed between the sleeve and the light-transmitting member.

6. The cooling fan with a data display function according to claim 1, wherein the frame body comprises an outer frame and a fixing plate, the fixing plate is located in a middle of the outer frame and connected to the outer frame through a plurality of connecting ribs, and wherein the driving unit is mounted on the fixing plate.

7. The cooling fan with a data display function according to claim 6, wherein one of the connecting ribs is provided with a clamping groove.

8. The cooling fan with a data display function according to claim 7, wherein shock absorbing pads are provided at four corners on both sides of the outer frame.

9. The cooling fan with a data display function according to claim 1, further comprising a controller, which is electrically connected to the driving unit.
